(19) United States
(12) Patent Application Publication
(10) Pub. No.: US 2026/0013168 A1
(43) Pub. Date: Jan. 8, 2026

(54) SEMICONDUCTOR DEVICE, SEMICONDUCTOR DEVICE MANUFACTURING METHOD, AND ELECTRONIC DEVICE

(71) Applicant: Fujitsu Limited, Kawasaki-shi (JP)

(72) Inventor: Atsushi YAMADA, Hiratsuka (JP)

(73) Assignee: Fujitsu Limited, Kawasaki-shi (JP)

(21) Appl. No.: 19/247,455

(22) Filed: Jun. 24, 2025

(30) Foreign Application Priority Data
Jul. 4, 2024 (JP) 2024-108272

(51) Int. Cl. H10D 30/47; H10D 30/01; H10D 62/85

(52) U.S. Cl. CPC H10D 30/475; H10D 30/015; H10D 62/8503

(57) ABSTRACT

A semiconductor device includes a nitride semiconductor layer, an inorganic insulating film, and a support substrate. The nitride semiconductor layer has a (0001) plane, which is a group-III polar plane, and a (000-1) plane, which is an N-polar plane, on a side opposite to the (0001) plane. A non-resin-based inorganic insulating film is formed on the (0001) plane side of the nitride semiconductor layer. The support substrate which supports the nitride semiconductor layer with the inorganic insulating film therebetween is formed on a side of the inorganic insulating film opposite to the nitride semiconductor layer.

### CROSS-REFERENCE TO RELATED APPLICATION

This application is based upon and claims the benefit of priority of Patent the prior Japanese Application No. 2024-108272, filed on Jul. 4, 2024, the entire contents of which are incorporated herein by reference.

### FIELD

The embodiments discussed herein relate to a semiconductor device, a semiconductor device manufacturing method, and an electronic device.

### BACKGROUND

A semiconductor device using a nitride semiconductor is known. For example, what is called an N-plane GaN-based semiconductor device is known in which a GaN-based semiconductor having two polar planes of a Ga-plane (Ga-polarity) and an N-plane (N-polarity) is used, and in which a semiconductor element is formed on the N-plane side of a GaN epitaxial substrate stacked in a Ga-polarity direction (See, for example, Japanese Laid-open Patent Publication No. 2017-228577).

### SUMMARY

According to one aspect, there is provided a semiconductor device including: a nitride semiconductor layer having a (0001) plane and a (000-1) plane opposite to the (0001) plane; a non-resin-based inorganic insulating film (0001) plane side of the nitride semiconductor layer where the (0001) plane is located; and a support substrate which is formed on a side of the inorganic insulating film opposite to the nitride semiconductor layer and which supports the nitride semiconductor layer with the inorganic insulating film therebetween.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a view for describing an example of a semiconductor device;

FIGS. 2A and 2B are views for describing an example of a method for forming a nitride semiconductor layer;

FIG. 3 is a view for describing an example of a semiconductor device according to a first embodiment;

FIGS. 4A and 4B are views for describing an example of the structure of the semiconductor device according to the first embodiment;

FIGS. 5A and 5B are views for describing an example of a method for manufacturing the semiconductor device according to the first embodiment (part 1);

FIGS. 6A and 6B are views for describing the example of the method for manufacturing the semiconductor device according to the first embodiment (part 2);

FIGS. 7A and 7B are views for describing the example of the method for manufacturing the semiconductor device according to the first embodiment (part 3);

FIGS. 8A and 8B are views for describing the example of the method for manufacturing the semiconductor device according to the first embodiment (part 4);

FIGS. 9A and 9B are views for describing the example of the method for manufacturing the semiconductor device according to the first embodiment (part 5);

FIGS. 10A and 10B are views for describing the example of the method for manufacturing the semiconductor device according to the first embodiment (part 6);

FIGS. 11A and 11B are views for describing the example of the method for manufacturing the semiconductor device according to the first embodiment (part 7);

FIGS. 12A and 12B are views for describing the example of the method for manufacturing the semiconductor device according to the first embodiment (part 8);

FIGS. 13A and 13B are views for describing an example of the characteristics of the semiconductor device according to the first embodiment;

FIG. 14 is a view for describing an example of a semiconductor package according to a second embodiment;

FIG. 15 is a view for describing an example of a power factor correction circuit according to a third embodiment;

FIG. 16 is a view for describing an example of a power supply device according to a fourth embodiment; and

FIG. 17 is a view for describing an example of an amplifier according to a fifth embodiment.

### DESCRIPTION OF EMBODIMENTS

With a semiconductor device in which a semiconductor element is formed on an N-polar plane, that is, on the (000-1) plane side of a nitride semiconductor layer, when a nitride semiconductor layer crystal-grown in an N-polar direction is used, it may be that a high-quality and high-performance semiconductor device is not obtained due to difficulty in crystal growth. On the other hand, the following method is also conceivable. A support substrate is bonded to a Ga-polar plane, that is, a (0001) plane side of a nitride semiconductor layer crystal-grown in a Ga-polar direction, an N-polar plane on the opposite side is exposed, and a semiconductor element is formed on the N-polar plane is also conceivable. With this method, however, a defect may occur on the Ga-polar plane side depending on how the support substrate is bonded and it may be that a high-quality and high-performance semiconductor device is not obtained.

A semiconductor device using a nitride semiconductor has been developed as a high breakdown voltage and high output device by utilizing characteristics such as a high saturation electron velocity and a wide band gap. As a semiconductor device using a nitride semiconductor, a field effect transistor (FET), for example, a high electron mobility transistor (HEMT) is known.

As an example of the HEMT, a HEMT using aluminum gallium nitride (AlGaN) as a barrier layer and gallium nitride (GaN) as a channel layer is known. The barrier layer is also referred to as an “electron supply layer”, and the channel layer is also referred to as an “electron transit layer”. With a such HEMT, piezoelectric polarization is generated in AlGaN due to spontaneous polarization of AlGaN and strain caused by a lattice constant difference between AlGaN and GaN and a two-dimensional electron gas (2DEG) region is created in GaN. As a result, a high output device is realized.

As the HEMT, a HEMT in which a transistor is realized by forming a gate electrode, a source electrode, a drain electrode, and the like on the group-III polar plane side, that is, on the (0001) plane side of a nitride semiconductor layer including a channel layer, a barrier layer, and the like is known. Hereinafter, for convenience, such a HEMT is also referred to as a “group-III polarity HEMT”.

In addition, a HEMT in which a transistor is realized by forming a gate electrode, a source electrode, a drain electrode, and the like on the N-polar plane side, that is, on the (000-1) plane side of a nitride semiconductor layer including a channel layer, a barrier layer, and the like is known. Hereinafter, for convenience, such a HEMT is also referred to as an “N-polarity HEMT”.

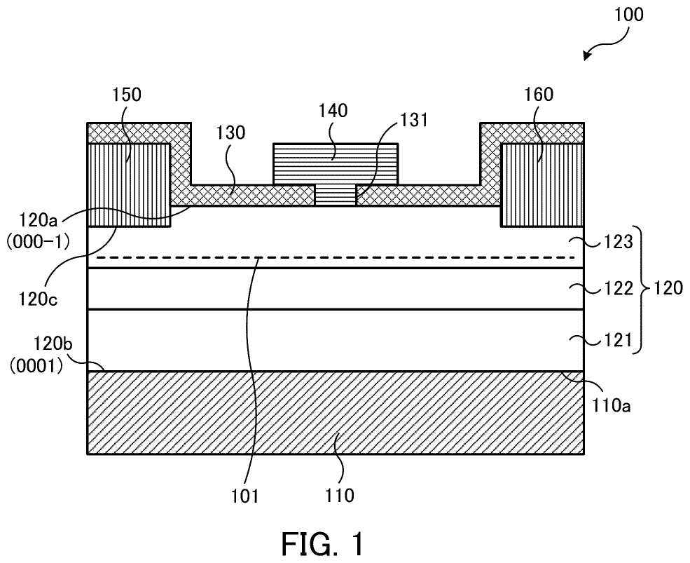

FIG. 1 is a view for describing an example of a semiconductor device. FIG. 1 is a fragmentary schematic sectional view of an example of a semiconductor device.

A semiconductor device 100 illustrated in FIG. 1 is an example of an N-polarity HEMT. The semiconductor device 100 includes a support substrate 110, a nitride semiconductor layer 120, a passivation film 130, a gate electrode 140, a source electrode 150, and a drain electrode 160.

A silicon carbide (Sic) substrate, a silicon (Si) substrate, a sapphire substrate, or the like is used as the support substrate 110. The nitride semiconductor layer 120 is formed on a predetermined surface 110a side of the support substrate 110. The nitride semiconductor layer 120 is formed so that a surface 120b on the support substrate 110 side is a group-III polar plane and so that a surface 120a on a side opposite to the support substrate 110 is an N-polar plane. That is, in the nitride semiconductor layer 120, the surface 120b side is a (0001) plane and the surface 120a side is a (000-1) plane.

The nitride semiconductor layer 120 includes, for example, a buffer layer 121, a barrier layer 122, and a channel layer 123. A nitride semiconductor such as GaN is used for forming the buffer layer 121. A nitride semiconductor such as AlGaN is used for forming the barrier layer 122. A nitride semiconductor such as GaN is used for forming the channel layer 123. A nitride semiconductor having a band gap larger than that of the channel layer 123 is used for forming the barrier layer 122. A 2DEG region 101 is generated in the channel layer 123 by spontaneous polarization of the barrier layer 122 and piezoelectric polarization generated in the barrier layer 122 due to strain caused by a lattice constant difference between the channel layer 123 and the barrier layer 122.

The gate electrode 140, the source electrode 150, and the drain electrode 160 are formed on the surface 120a side of the nitride semiconductor layer 120, that is, on the (000-1) plane side which is an N-polar plane. The gate electrode 140 is formed between the source electrode 150 and the drain electrode 160. Metal such as nickel (Ni) or gold (Au) is used for forming the gate electrode 140. The gate electrode 140 is formed to function as, for example, a Schottky electrode. Furthermore, metal such as tantalum (Ta) or aluminum (Al) is used for forming the source electrode 150 and the drain electrode 160. The source electrode 150 and the drain electrode 160 are formed to function as an ohmic electrode. The source electrode 150 and the drain electrode 160 are formed, for example, in recesses 120c formed on the surface 120a side of the nitride semiconductor layer 120.

The passivation film 130 is formed on the surface 120a side of the nitride semiconductor layer 120. An insulating material such as SiN is used for forming the passivation film 130. The passivation film 130 partially covers the surface 120a of the nitride semiconductor layer 120 between the source electrode 150 and the drain electrode 160. The passivation film 130 may be formed on the source electrode 150 and the drain electrode 160. The passivation film 130 has an opening portion 131 in a part between the source electrode 150 and the drain electrode 160. The gate electrode 140 is formed in the opening portion 131 of the passivation film 130.

When the semiconductor device 100 having the above structure operates, a relatively high voltage (drain voltage) with respect to the source electrode 150 is applied to the drain electrode 160 and a predetermined voltage (gate voltage) is applied to the gate electrode 140. The amount of electric charge passing through the 2DEG region 101 below the gate electrode 140 between the source electrode 150 and the drain electrode 160 is controlled by a field effect of the gate voltage applied to the gate electrode 140 and an output (drain current) is controlled. The transistor function of the semiconductor device 100 is realized in this way.

With the semiconductor device 100 having the above structure, that is, with the N-polarity HEMT, it is expected that, for example, controllability by the gate electrode 140 is improved and a leakage current is suppressed, compared with the group-III polarity HEMT.

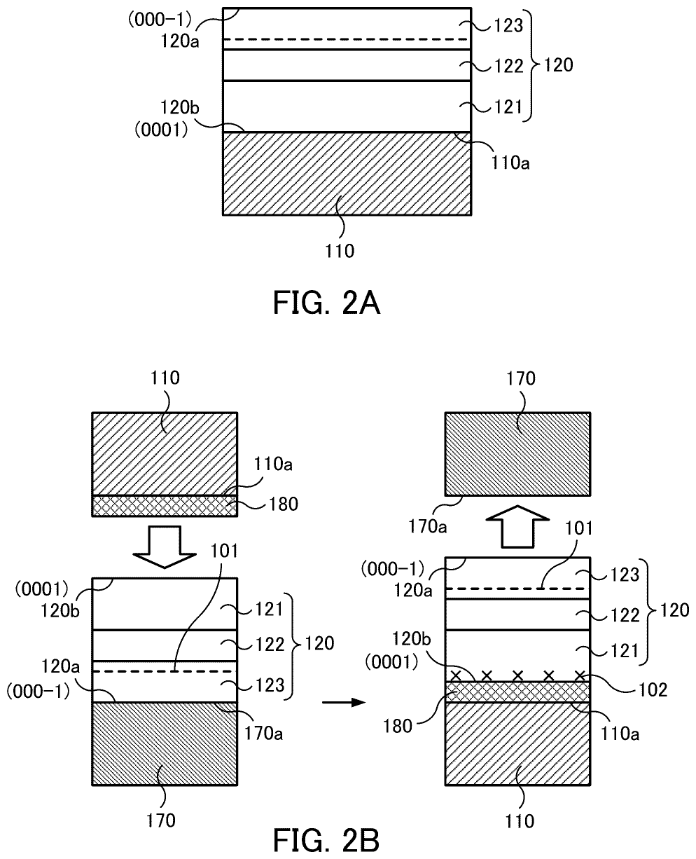

As a method for forming the nitride semiconductor layer 120 in the above semiconductor device 100, for example, a method illustrated in FIGS. 2A and 2B is considered.

FIGS. 2A and 2B are views for describing an example of a method for forming a nitride semiconductor layer. Here, FIG. 2A is a view for describing a first example of a method for forming a nitride semiconductor layer. FIG. 2B is a view for describing a second example of a method for forming a nitride semiconductor layer.

With the method illustrated in FIG. 2A, the nitride semiconductor layer 120 is crystal-grown in an N-polarity direction on the surface 110a side of the support substrate 110 by the use of a metal organic chemical vapor deposition method. With this method, the buffer layer 121, the barrier layer 122, and the channel layer 123 of the nitride semiconductor layer 120 are crystal-grown in order from the surface 110a side of the support substrate 110 so that a surface of each layer on a side opposite to the support substrate 110 side is a (000-1) plane. As a result, the nitride semiconductor layer 120 having a (000-1) plane, which is an N-polar plane, on the surface 120a opposite to the support substrate 110 side and having a (0001) plane, which is a group-III polar plane, on the surface 120b on the support substrate 110 side is formed. For example, the nitride semiconductor layer 120 formed in this way is used and the gate electrode 140, the source electrode 150, the drain electrode 160, and the like are formed on the surface 120a side. By doing so, an N-polarity HEMT is formed.

With the method illustrated in FIG. 2A, the nitride semiconductor layer 120 is crystal-grown in an N-polarity direction. With this method, however, the number of impurities, such as oxygen (O), taken into the nitride semiconductor layer 120 is larger than that of impurities taken into the nitride semiconductor layer 120 in a case where the nitride semiconductor layer 120 is crystal-grown in a group-III polarity direction. For example, when O is taken into the nitride semiconductor layer 120 at relatively high concentration, the nitride semiconductor layer 120 (channel layer 123 and the like thereof) may become n-type. When O concentration in the nitride semiconductor layer 120 increases, the mobility of electrons as carriers of the N-polarity HEMT may decrease or a leakage current may increase. With the method illustrated in FIG. 2A, impurities such as O are taken into the nitride semiconductor layer 120 because the nitride semiconductor layer 120 is crystal-grown in an N-polarity direction. As a result, it may be that a high-performance N-polarity HEMT having a high-quality nitride semiconductor layer 120 and having sufficient characteristics is not obtained.

On the other hand, the method illustrated in FIG. 2B uses crystal growth of the nitride semiconductor layer 120 in a group-III polarity direction.

With this method, as illustrated in the left drawing of FIG. 2B, first the nitride semiconductor layer 120 is crystal-grown in a group-III polarity direction on a surface 170a side of a growth substrate 170 made of sapphire or the like by the use of the metal organic chemical vapor deposition method. At this time, each of the channel layer 123, the barrier layer 122, and the buffer layer 121 of the nitride semiconductor layer 120 is crystal-grown in order from the surface 170a side of the growth substrate 170 so that a surface of each layer on a side opposite to the growth substrate 170 side is a (0001) plane. As a result, the nitride semiconductor layer 120 having a (0001) plane, which is a group-III polar plane, on the surface 120b opposite to the growth substrate 170 side and having a (000-1) plane, which is an N-polar plane, on the surface 120a on the growth substrate 170 side is formed. Furthermore, the support substrate 110 is bonded to the surface 120b, which is a (0001) plane, of the nitride semiconductor layer 120 via a resin-based adhesive layer 180 such as hydrogen silsesquioxane (HSQ). At this time, as illustrated in the left drawing of FIG. 2B, the support substrate 110 having the adhesive layer 180 on the surface 110a is bonded to the surface 120b of the nitride semiconductor layer 120 via the adhesive layer 180. For example, resin such as HSQ is applied to the surface 110a of the support substrate 110 and is hardened in a state in which the resin is in contact with the surface 120b of the nitride semiconductor layer 120. By doing so, the adhesive layer 180 by which the support substrate 110 and the nitride semiconductor layer 120 are bonded is formed.

After that, as illustrated in the right drawing of FIG. 2B, the growth substrate 170 on the (000-1) plane side, that is, on the surface 120a side of the nitride semiconductor layer 120 is removed by peeling or the like. As a result, the nitride semiconductor layer 120 having a (000-1) plane, which is an N-polar plane, on the surface 120a opposite to the support substrate 110 side and having a (0001) plane, which is a group-III polar plane, on the surface 120b on the support substrate 110 side is formed. For example, the nitride semiconductor layer 120 formed in this way is used and the gate electrode 140, the source electrode 150, the drain electrode 160, and the like are formed on the surface 120a side. By doing so, an N-polarity HEMT is formed.

With the method illustrated in FIG. 2B, the support substrate 110 is bonded to the nitride semiconductor layer 120 crystal-grown in the group-III polarity direction via the adhesive layer 180 such as HSQ. With this method, however, a defect 102 may occur at the interface between the nitride semiconductor layer 120 and the adhesive layer 180. The reason for this is that dangling bonds on the surface of the nitride semiconductor layer 120 are not sufficiently terminated by the adhesive layer 180 such as HSQ or that the surface of the nitride semiconductor layer 120 is amorphized by the adhesive layer 180. In addition, creation of stress due to a state change such as hardening of the adhesive layer 180 may also be considered as a reason for generation of the defect 102. Instability of a surface state on the (0001) plane, which is a group-III polar plane, of the nitride semiconductor layer 120 may be a factor that causes the occurrence of the defect 102. The occurrence of the defect 102 may be a factor that causes the occurrence of current collapse or the like at the time of the operation of the N-polarity HEMT. With the method illustrated in FIG. 2B, it may be that a high-performance N-polarity HEMT having a high-quality nitride semiconductor layer 120 in which the occurrence of the defect 102 is suppressed and having sufficient characteristics is not obtained.

Furthermore, for example, a film formed by the use of HSQ may be porous and have relatively low thermal conductivity. If a material, such as HSQ, having relatively low thermal conductivity is used as the adhesive layer 180, the property of conducting heat from the nitride semiconductor layer 120, which generates the heat in accordance with the operation of the N-polarity HEMT, to the support substrate 110 may deteriorate. The deterioration in the property of conducting heat from the nitride semiconductor layer 120 to the support substrate 110 may cause overheat of the nitride semiconductor layer 120 and may cause deterioration in the operation performance of the N-polarity HEMT formed in the nitride semiconductor layer 120.

In view of the above points, a high-quality and high-performance semiconductor device is realized by adopting structure described below as an embodiment.

### First Embodiment

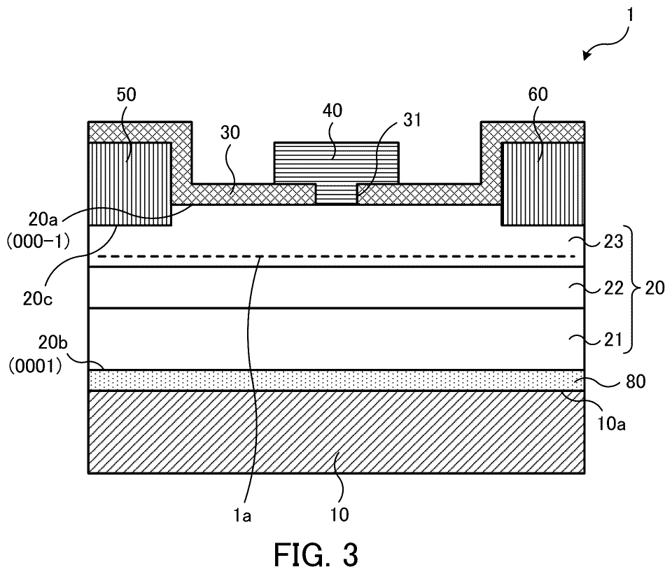

FIG. 3 is a view for describing an example of a semiconductor device according to a first embodiment. FIG. 3 is a fragmentary schematic sectional view of an example of a semiconductor device.

A semiconductor device 1 illustrated in FIG. 3 is an example of an N-polarity HEMT. The semiconductor device 1 includes a support substrate 10, an inorganic insulating film 80, a nitride semiconductor layer 20, a passivation film 30, a gate electrode 40, a source electrode 50, and a drain electrode 60.

Various substrates are used as the support substrate 10. For example, a SiC substrate, a Si substrate, a single crystal diamond substrate, a polycrystalline diamond substrate, an aluminum nitride (AlN) substrate, a GaN substrate, a sapphire substrate, or the like is used as the support substrate 10. The support substrate 10 preferably has relatively high thermal conductivity, for example, thermal conductivity higher than that of the nitride semiconductor layer 20 and the inorganic insulating film 80. The support substrate 10 having relatively high thermal conductivity is a SiC substrate, a Si substrate, a single crystal a diamond substrate, polycrystalline diamond substrate, an AlN substrate, or the like. For example, the nitride semiconductor layer 20 is formed on a predetermined surface 10a side of the support substrate 10 with the inorganic insulating film 80 therebetween.

As stated above, the support substrate 10 is a support substrate for supporting the nitride semiconductor layer 20 with the inorganic insulating film 8 therebetween. The support substrate 10 may be a heat dissipation substrate for dissipating heat generated in the nitride semiconductor layer 20 to the outside. A substrate in which circuit elements such as transistors and wirings are not formed or incorporated is used as the support substrate 10.

The inorganic insulating film 80 is formed on a surface 10a of the support substrate 10. A film containing various non-resin inorganic insulating materials may be used as the inorganic insulating film 80. It is preferable relatively high thermal to use a material having conductivity, for example, an inorganic insulating material having thermal conductivity higher than that of a resin-based insulating material, such as HSQ or an organic resin, for forming the inorganic insulating film 80.

A film containing an oxide, a nitride, or an oxynitride of at least one of Si, Ti, and Al may be used as the inorganic insulating film 80. For example, silicon oxide (SiO), silicon nitride (SiN), silicon oxynitride (SiON), titanium oxide (TiO), titanium nitride (TiN), titanium oxynitride (TiON), aluminum oxide (AlO), AlN, aluminum oxynitride (AlON), or the like is used for forming the inorganic insulating film 80. In addition, an oxide, such as TiSiO, AlSiO, or TiAlO, containing two of Si, Ti, and Al, a nitride, such as TiSiN, AlSiN, or TiAlN, containing two of Si, Ti, and Al, or an oxynitride, such as TiSiON, AlSiON, or TiAlON, containing two of Si, Ti, and Al may be used for forming the inorganic insulating film 80. Alternatively, an oxide, a nitride, or an oxynitride containing Si, Ti, and Al may be used for forming the inorganic insulating film 80.

The inorganic insulating film 80 may have a single-layer structure including one kind of inorganic insulating material film or may have a laminated structure including two or more layers of the same kind or different kinds of inorganic insulating material films.

The thickness of the inorganic insulating film 80 in a direction perpendicular to the surface 10a of the support substrate 10 (in a normal direction) is set to, for example, 5 nm or more and 50 nm or less, and preferably 20 nm. In the following description, the term “thickness” also refers to thickness in a direction perpendicular to the surface 10a of the support substrate 10.

The nitride semiconductor layer 20 is formed on a side opposite to the support substrate 10 side of the inorganic insulating film 80. The nitride semiconductor layer 20 is formed so that a surface 20b on the inorganic insulating film 80 side is a group-III polar plane and so that a surface 20a on a side opposite to the inorganic insulating film 80 side is an N-polar plane. That is, with the nitride semiconductor layer 20, the surface 20b on the inorganic insulating film 80 side is a (0001) plane and the surface 20a opposite to the inorganic insulating film 80 side is a (000-1) plane.

The nitride semiconductor layer 20 includes, for example, a buffer layer 21, a barrier layer 22, and a channel layer 23. A nitride semiconductor, such as GaN, is layer used for forming the buffer 21. A nitride semiconductor, as such AlGaN, indium aluminum gallium nitride (InAlGaN), indium aluminum nitride (InAlN), or AlN, is used for forming the barrier layer 22. A nitride semiconductor, such as GaN, is used for forming the channel layer 23. A nitride semiconductor having a band gap larger than that of a nitride semiconductor used for forming the channel layer 23 is used for forming the barrier layer 22. A 2DEG region 1a is generated in the channel layer 23 by spontaneous polarization of the barrier layer 22 and piezoelectric polarization generated in the barrier layer 22 due to strain caused by a lattice constant difference between the barrier layer 22 and the channel layer 23. The thickness of the buffer layer 21 is set to, for example, 200 nm. The thickness of the barrier layer 22 is set to, for example, 20 nm. The thickness of the channel layer 23 is set to, for example, 200 nm or less, preferably 50 nm.

A nitride semiconductor contained in the channel layer 23 is also referred to as a “first nitride semiconductor”, a nitride semiconductor contained in the barrier layer 22 is also referred to as a “second nitride semiconductor”, and a nitride semiconductor contained in the buffer layer 21 is also referred to as a “third nitride semiconductor”.

The nitride semiconductor layer 20, that is, the buffer layer 21, the barrier layer 22, and the channel layer 23 in this example, is formed by crystal growth by the use of the metal organic chemical vapor deposition (MOCVD) or a metal organic vapor phase epitaxy (MOVPE) method, a molecular beam epitaxy (MBE) method, or the like. The nitride semiconductor layer 20 is formed on the surface 10a of the support substrate 10 with the inorganic insulating film 80 therebetween in the following way. For example, the channel layer 23, the barrier layer 22, and the buffer layer 21 are crystal-grown in this order in a group-III polarity direction on a predetermined growth substrate. The support substrate 10 is bonded to a group-III polar plane of the buffer layer 21, which is the uppermost layer at this time, with the inorganic insulating film 80 therebetween. After that, the growth substrate is removed from an N-polar plane opposite to the group-III polar plane. For example, this method is used to form a structure in which the nitride semiconductor layer 20 is formed on the support substrate 10 with the inorganic insulating film 80 therebetween, that is, a structure in which the nitride semiconductor layer 20 is supported by the support substrate 10 with the inorganic insulating film 80 therebetween.

The details of a method for manufacturing the semiconductor device 1 (N-polarity HEMT) including the formation of the nitride semiconductor layer 20 will be described later.

The nitride semiconductor layer 20 having three layers of the buffer layer 21, the barrier layer 22, and the channel layer 23 is taken as an example. However, layers which make up the nitride semiconductor layer 20 are not limited to three layers of the buffer layer 21, the barrier layer 22, and the channel layer 23. For example, the buffer layer 21 may be omitted. In this case, the support substrate 10 is bonded to a group-III polar plane of the barrier layer 22 with the inorganic insulating film 80 therebetween. In addition, a barrier layer made of AlGaN, AlN, or the like may be further formed on a side of the channel layer 23 opposite to the barrier layer 22 to realize a quantum confinement structure. A layer made of AlGaN, indium gallium nitride (InGaN), or the like may be formed as a spacer layer between the channel layer 23 and the barrier layer 22. A layer made of GaN or the like may be formed as a cap layer on a side of the channel layer 23 opposite to the barrier layer 22. The nitride semiconductor layer 20 may include, in addition to the barrier layer 22 and the channel layer 23 (and the buffer layer 21), one or more of a barrier layer, a spacer layer, a cap layer, and the like for a quantum confinement structure.

The gate electrode 40, the source electrode 50, and the drain electrode 60 are formed on the surface 20a side, that is, on the (000-1) plane side, which is the N-polar plane side, of the nitride semiconductor layer 20. The gate electrode 40 is formed between the source electrode 50 and the drain electrode 60.

Metal such as Ni or Au is used for forming the gate electrode 40. The gate electrode 40 is formed to function as, for example, a Schottky electrode. Although not illustrated, the gate electrode 40 may be formed on the surface 20a side of the nitride semiconductor layer 20 with a gate insulating film therebetween to form a metal insulator semiconductor (MIS) gate structure.

Metal such as Ta or Al is used for forming the source electrode 50 and the drain electrode 60. The source electrode 50 and the drain electrode 60 are formed to function as an ohmic electrode. The source electrode 50 and the drain electrode 60 are formed, for example, in recesses 20c formed in the surface 20a of the nitride semiconductor layer 20.

The passivation film 30 is formed on the surface 20a side of the nitride semiconductor layer 20. An insulating material, such as SiN, is used for forming the passivation film 30. The passivation film 30 partially covers the surface 20a of the nitride semiconductor layer 20 between the source electrode 50 and the drain electrode 60. The passivation film 30 may be formed on the source electrode 50 and the drain electrode 60. The passivation film 30 has an opening portion 31 in a part between the source electrode 50 and the drain electrode 60. The gate electrode 40 is formed in the opening portion 31 of the passivation film 30.

When the semiconductor device 1 having the above structure operates, a relatively high voltage (drain voltage) with respect to the source electrode 50 is applied to the drain electrode 60 and a predetermined voltage (gate voltage) is applied to the gate electrode 40. The amount of electric charge passing through the 2DEG region 1a below the gate electrode 40 between the source electrode 50 and the drain electrode 60 is controlled by a field effect of the gate voltage applied to the gate electrode 40 and an output (drain current) is controlled. The transistor function of the semiconductor device 1 is realized in this way.

As described above, with the semiconductor device 1 the nitride semiconductor layer 20 is formed on the surface 10a side of the support substrate 10 with the inorganic insulating film 80 therebetween. As described later in detail, the channel layer 23, the barrier layer 22, the buffer layer 21, and the like are crystal-grown in a group-III polarity direction and are used as the nitride semiconductor layer 20. The support substrate 10 is bonded to the group-III polar plane (surface 20b) side of the nitride semiconductor layer 20 crystal-grown in the group-III polarity direction with the inorganic insulating film 80 therebetween. By using the nitride semiconductor layer 20 crystal-grown in the group-III polarity direction, incorporation of impurities, such as O, into the nitride semiconductor layer 20 is suppressed and a decrease in carrier mobility, an increase in leakage current, and the like caused by impurities are suppressed.

Furthermore, with the semiconductor device 1, the inorganic insulating film 80 is formed between the nitride semiconductor layer 20 and the support substrate 10 and the nitride semiconductor layer 20 is protected by the inorganic insulating film 80. By forming the inorganic insulating film 80, dangling bonds on the surface 20b of the nitride semiconductor layer 20 are sufficiently terminated or amorphization of the surface 20b is suppressed. In addition, by forming the inorganic insulating film 80, it is possible to suppress creation of stress or the like due to a state change, such as hardening of an adhesive layer 180, for example, in the case of using the resin-based adhesive layer 180 such as HSQ. Since the nitride semiconductor layer 20 is protected by the inorganic insulating film 80, instability of a surface state on the group-III polar plane (surface 20b) of the nitride semiconductor layer 20 is suppressed and the occurrence of defects at an interface between the nitride semiconductor layer 20 and the inorganic insulating film 80 is suppressed. By suppressing the occurrence of defects in the nitride semiconductor layer 20, the occurrence of a current collapse or the like at the time of the operation of the semiconductor device 1 is suppressed.

In addition, with the semiconductor device 1, if a material having relatively high thermal conductivity is used as the inorganic insulating film 80, deterioration in the property of conducting heat from the nitride semiconductor layer 120, which generates the heat in accordance with the operation, to the support substrate 110 is suppressed. Furthermore, if a substrate having relatively high thermal conductivity is used as the support substrate 10, the property of dissipating to the outside the heat conducted from the nitride semiconductor layer 20 to the support substrate 10 via the inorganic insulating film 80 is enhanced. This suppresses deterioration in the operation performance of the semiconductor device 1 caused by overheat of the nitride semiconductor layer 20.

By adopting the above structure, a high-quality and high-performance semiconductor device 1, that is, an N-polarity HEMT is realized.

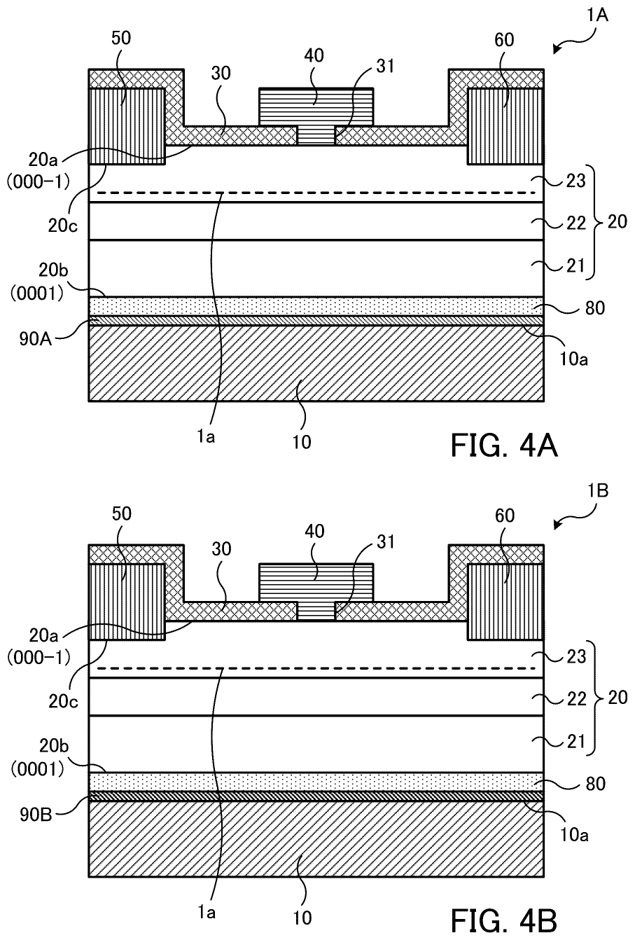

FIGS. 4A and 4B are views for describing an example of the structure of the semiconductor device according to the first embodiment. Each of FIGS. 4A and 4B is a fragmentary schematic sectional view of an example of the semiconductor device.

A semiconductor device 1A illustrated in FIG. 4A has a structure in which an amorphous layer 90A is formed between a support substrate 10 and an inorganic insulating film 80.

For example, the amorphous layer 90A contains a constituent element of the support substrate 10. For example, as described later, the support substrate 10 and the inorganic insulating film 80 are bonded to each other after surface activation is performed on a surface of the support substrate 10 on the side bonded to the inorganic insulating film 80 and surface of the inorganic insulating film 80 on the side bonded to the support substrate 10 by irradiation with ion beams such as argon (Ar). The amorphous layer 90A is formed at an interface between the support substrate 10 and the inorganic insulating film 80 bonded in this way after the surface activation. For example, when bonding is performed after the surface activation, the surface on the support substrate 10 side is amorphized and the amorphous layer 90A containing the constituent element of the support substrate 10 is formed. When bonding is performed after the surface activation, the surface on the inorganic insulating film 80 side may be amorphized. In this case, the amorphous layer 90A may contain a constituent element of the inorganic insulating film 80 in addition to the constituent element of the support substrate 10.

With the semiconductor device 1A, the amorphous layer 90A, for example, the amorphous layer 90A formed through the surface activation is located between the support substrate 10 and the inorganic insulating film 80. As a result, the support substrate 10 and the inorganic insulating film 80 are strongly bonded to each other.

Furthermore, a semiconductor device 1B illustrated in FIG. 4B has a structure in which a metal layer 90B is formed between a support substrate 10 and an inorganic insulating film 80.

Various metals are used for forming the metal layer 90B. For example, the metal layer 90B contains at least one of Si, germanium (Ge), tin (Sn), Ti, Al, indium (In), Ni, Au, platinum (Pt), Ta, niobium (Nb), vanadium (V), chromium (Cr), zirconium (Zr), molybdenum (MO), hafnium (Hf), and tungsten (W). The metal layer 90B may have a laminated structure including a metal layer formed on the support substrate 10 side and a metal layer formed on the inorganic insulating film 80 side. For example, as described later, metal layers are formed on a surface of the support substrate 10 to be bonded to the inorganic 80 surface of the inorganic insulating film and a insulating film 80 to be bonded to the support substrate 10 by a sputtering method or the like. These metal layers are bonded to each other by atomic diffusion. As a result, the metal layer 90B is formed.

With the semiconductor device 1B, the metal layer 90B, for example, the metal layer 90B bonded by atomic diffusion is formed between the support substrate 10 and the inorganic insulating film 80. As a result, the support substrate 10 and the inorganic insulating film 80 are strongly bonded to each other.

If the support substrate 10 and the inorganic insulating film 80 are bonded to each other with the metal layer 90B therebetween, a buffer layer 21 of a nitride semiconductor layer 20 is preferably formed between a barrier layer 22 and the inorganic insulating film 80 without being omitted. The conductive metal layer 90B may have an electrical effect on a channel layer 23 and the barrier layer 22 for realizing a transistor function.

Therefore, if the metal layer 90B is formed, it is preferable to form the buffer layer 21 and keep distance between the metal layer 90B and the channel layer 23 and the barrier layer 22. By doing so, such an electrical effect is suppressed. In this case, it is preferable to set the thickness of the buffer layer 21 to a certain value or greater by which an electrical effect caused by the metal layer 90B is suppressed.

Next, a method for manufacturing the semiconductor devices 1, 1A, or 1B (also referred to as “the semiconductor device 1 or the like”) having the above structure will be described.

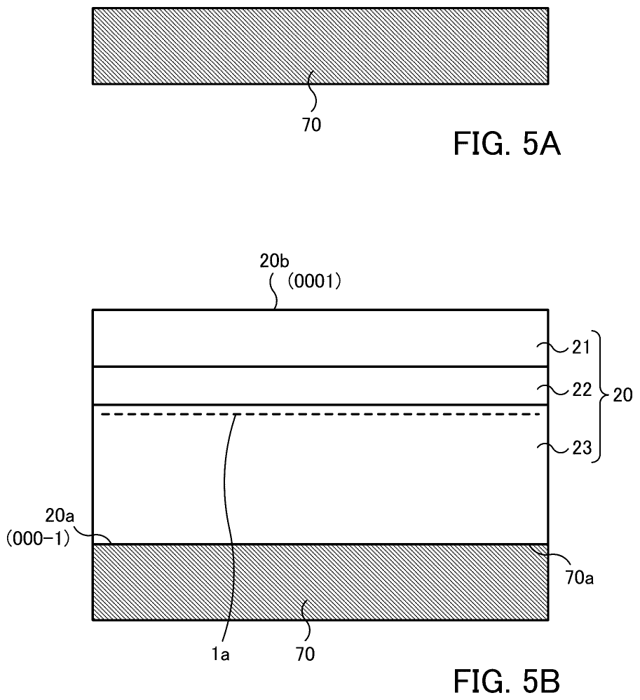

FIGS. 5A to 12B are views for describing an example of a method for manufacturing the semiconductor device according to the first embodiment. Each process for manufacturing the semiconductor device 1 or the like according to the first embodiment will now be described.

FIG. 5A is a fragmentary schematic sectional view of a growth substrate 70. To manufacture the semiconductor device 1 or the like, first the growth substrate 70 illustrated in FIG. 5A is prepared. Various substrates are used as the growth substrate 70. For example, a sapphire substrate is used as the growth substrate 70. In addition, a SiC substrate, a Si substrate, a diamond substrate, an AlN substrate, a GaN substrate, or the like may be used as the growth substrate 70.

FIG. 5B is a fragmentary schematic sectional view of a process for forming the nitride semiconductor layer 20. As illustrated in FIG. 5B, the nitride semiconductor layer 20 is formed on the predetermined surface 70a side of the prepared growth substrate 70 by the use of the MOVPE method or the like. The nitride semiconductor layer 20 is formed by crystal-growing the channel layer 23, the barrier layer 22, and the buffer layer 21 in this order from the surface 70a side of the growth substrate 70 in a group-III polarity direction. For example, a GaN layer having a thickness of 1000 nm is formed as the channel layer 23. An AlGaN layer, an InAlGaN layer, an InAlN layer, or an AlN layer having a thickness of 20 nm is formed as the barrier layer 22. A GaN layer having a thickness of 200 nm is formed as the buffer layer 21. The 2DEG region 1a is generated in the channel layer 23 near the junction interface between the channel layer 23 and the barrier layer 22.

The buffer layer 21 of the nitride semiconductor layer 20 may be omitted. Furthermore, the nitride semiconductor layer 20 may include one or more of a barrier layer for a quantum confinement structure, a spacer layer, a cap layer, and the like described above.

When each layer of the nitride semiconductor layer 20 is crystal-grown by the use of the MOVPE method, tri-methyl-gallium (TMGa) is used as a Ga source. Tri-methyl-aluminum (TMAl) is used as an Al source. Tri-methyl-indium (TMIn) is used as an In source. ammonia (NH₃) is used as an N source. The supply and stoppage (switching) of a raw material, such as TMGa, TMAl, or TMIn, and a flow rate at the time of supply (ratio of mixing with the other raw materials) are properly set according to nitride semiconductors to be crystal-grown. Hydrogen (H₂) or nitrogen (N₂) is used as carrier gas. A pressure condition at the time of crystal growth is in the range of about 1 to 100 kPa. A temperature condition at the time of crystal growth is in the range of about 600 to 1500° C.

By crystal growth in a group-III polarity direction by the MOVPE method, the nitride semiconductor layer 20 having a (000-1) plane, which is an N-polar plane, on the surface 20a on the growth substrate 70 side and having a (0001) plane, which is a group-III polar plane, on the surface 20b opposite to the growth substrate 70 side is formed. Since the nitride semiconductor layer 20 is formed by crystal growth in a group-III polarity direction, incorporation of impurities, such as O, into the nitride semiconductor layer 20 is suppressed. As a result, with the semiconductor device 1 or the like in which the nitride semiconductor layer 20 is used, a decrease in carrier mobility, an increase in leakage current, and the like caused by impurities in the nitride semiconductor layer 20 are suppressed.

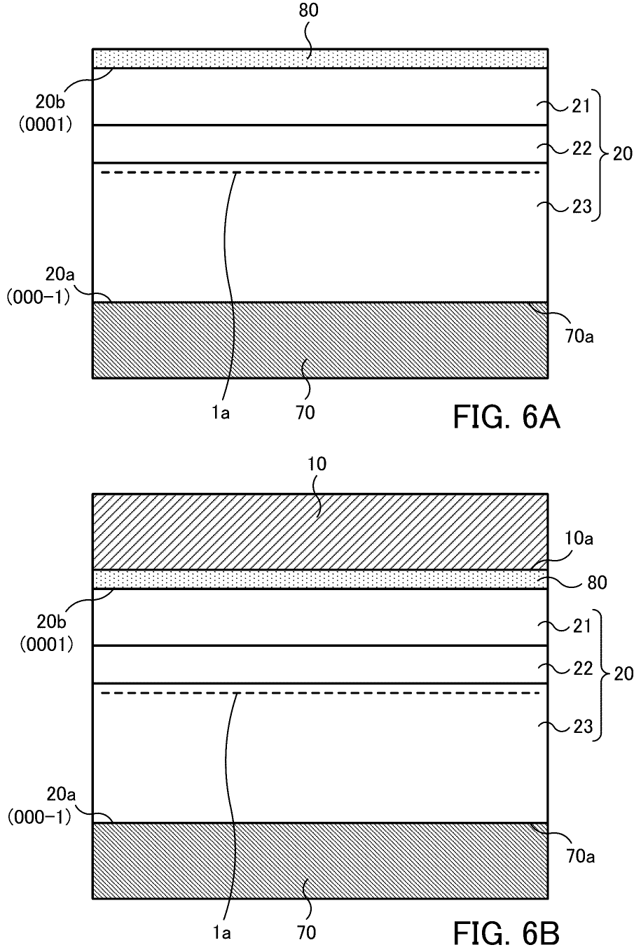

FIG. 6A is a fragmentary schematic sectional view of a process for forming the inorganic insulating film 80. After the nitride semiconductor layer 20 is formed, as illustrated in FIG. 6A, the inorganic insulating film 80 is formed on the surface 20b ((0001) plane), which is a group-III polar plane, of the nitride semiconductor layer 20. A film containing a non-resin inorganic insulating material is used as the inorganic insulating film 80. For example, a film containing an oxide, a nitride, or an oxynitride of at least one of Si, Ti, and Al is formed as the inorganic insulating film 80. For example, a film using SiN is used as the inorganic insulating film 80. The inorganic insulating film 80 is formed on the surface 20b of the nitride semiconductor layer 20 by the use of, for example, a plasma CVD method. In addition, the inorganic insulating film 80 may be formed by the use of an atomic layer deposition (ALD) method, the sputtering method, a thermal CVD method, or the like.

The inorganic insulating film 80 has the function of protecting the surface 20b of the nitride semiconductor layer 20. Since the surface 20b of the nitride semiconductor layer 20 is protected by the inorganic insulating film 80, instability of a surface state on the surface 20b side is suppressed and the occurrence of defects at an interface between the nitride semiconductor layer 20 and the inorganic insulating film 80 is suppressed. This suppresses the occurrence of a current collapse or the like at the time of the operation of the semiconductor device 1 or the like in which the nitride semiconductor layer 20 is used. In addition, by using the above insulating material, such as SiN, as the inorganic insulating film 80, the thermal resistance of the inorganic insulating film 80 becomes relatively low. As a result, with the semiconductor device 1 or the like in which the nitride semiconductor layer 20 is used, deterioration in the property of conducting heat from the nitride semiconductor layer 20 to the support substrate 10 (bonded to the inorganic insulating film 80 in a way described later) via the inorganic insulating film 80 is suppressed.

The thickness of the inorganic insulating film 80 is set to, for example, 5 nm or more and 50 nm or less, preferably 20 nm. If the thickness of the inorganic insulating film 80 is less than 5 nm, the function of protecting the surface 20b of the nitride semiconductor layer 20 is not sufficiently obtained and the possibility of defects occurring in the nitride semiconductor layer 20 may increase. Furthermore, if the thickness of the inorganic insulating film 80 exceeds 50 nm, the thermal resistance of the inorganic insulating film 80 becomes relatively high and the possibility that the property of conducting heat from the nitride semiconductor layer 20 to the support substrate 10 deteriorates may increase.

FIG. 6B is a fragmentary schematic sectional view of a process for bonding the support substrate 10. After the inorganic insulating film 80 is formed, as illustrated in FIG. 6B, the support substrate 10 is bonded to the inorganic insulating film 80. The surface 10a of the support substrate 10 is bonded to the inorganic insulating film 80. It is preferable to use a substrate, such as a SiC substrate, a Si substrate, a single crystal diamond substrate, a polycrystalline diamond substrate, or an AlN substrate, having relatively high thermal conductivity as the support substrate 10 bonded to the inorganic insulating film 80. If the support substrate 10 having relatively high thermal conductivity is used, the property of dissipating to the outside heat conducted from the nitride semiconductor layer 20 to the support substrate 10 via the inorganic insulating film 80 is enhanced.

Depending on the kinds of the support substrate 10 and the inorganic insulating film 80, the support substrate 10 and the inorganic insulating film 80 are bonded in a state in which they are in direct contact with each other. However, a method for bonding the support substrate 10 and the inorganic insulating film 80 is not limited to such a direct bonding method. Various methods are used for bonding the support substrate 10 and the inorganic insulating film 80.

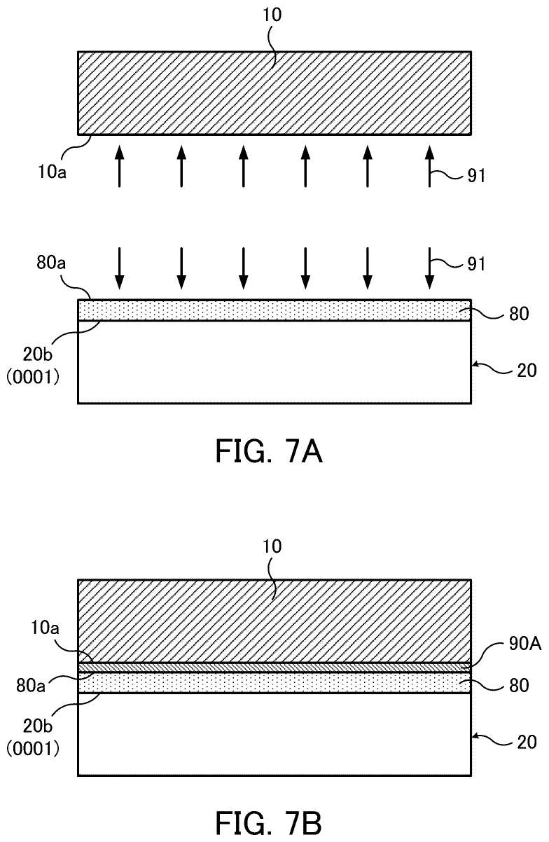

For example, the support substrate 10 and the inorganic insulating film 80 are bonded to each other by the use of a method illustrated in FIGS. 7A and 7B. FIG. 7A is a fragmentary schematic sectional view of a process for surface activation of the support substrate 10 and the inorganic insulating film 80. FIG. 7B is a fragmentary schematic sectional view of a process for bonding the support substrate 10 and the inorganic insulating film 80.

For example, as illustrated in FIG. 7A, the surface 10a of the support substrate 10 to be bonded to the inorganic insulating film 80 and the surface 80a of the inorganic insulating film 80 to be bonded to the support substrate 10 are irradiated with ion beams 91 of Ar or the like in a vacuum (also referred to as “ion beam irradiation”). Irradiation with the ion beams 91 activates the surface 10a of the support substrate 10 and the surface 80a of the inorganic insulating film 80 (also referred to as “surface activation”).

After the surface activation, as illustrated in FIG. 7B, the surface 10a of the support substrate 10 and the surface 80a of the inorganic insulating film 80 are brought into contact with each other in a vacuum. As a result, the support substrate 10 and the inorganic insulating film 80 are bonded to each other. An amorphous layer 90A is formed at an interface between the support substrate 10 and the inorganic insulating film 80 bonded in this way after the surface activation. For example, when the support substrate 10 and the inorganic insulating film 80 are bonded after the surface activation, the surface 10a of the support substrate 10 is amorphized and the amorphous layer 90A containing a constituent element of the support substrate 10 is formed.

When the support substrate 10 and the inorganic insulating film 80 are bonded after the surface activation, the surface 80a of the inorganic insulating film 80 may be amorphized, in addition to the surface 10a of the support substrate 10. In this case, the amorphous layer 90A may contain a constituent element of the inorganic insulating film 80 in addition to a constituent element of the support substrate 10.

In addition, an example in which surface activation is performed on the surface 10a of the support substrate 10 and the surface 80a of the inorganic insulating film 80 has been described. However, surface activation may be performed on the surface 10a or the surface 80a. Even in this case, the support substrate 10 and the inorganic insulating film 80 are bonded to each other.

If the thickness of the inorganic insulating film 80 is less than 5 nm at the time of performing surface activation by ion beam irradiation, damage at ion beam irradiation time may reach the nitride semiconductor layer 20. Therefore, if surface activation is performed on the inorganic insulating film 80 by ion beam irradiation, the thickness of the inorganic insulating film 80 is preferably 5 nm or more.

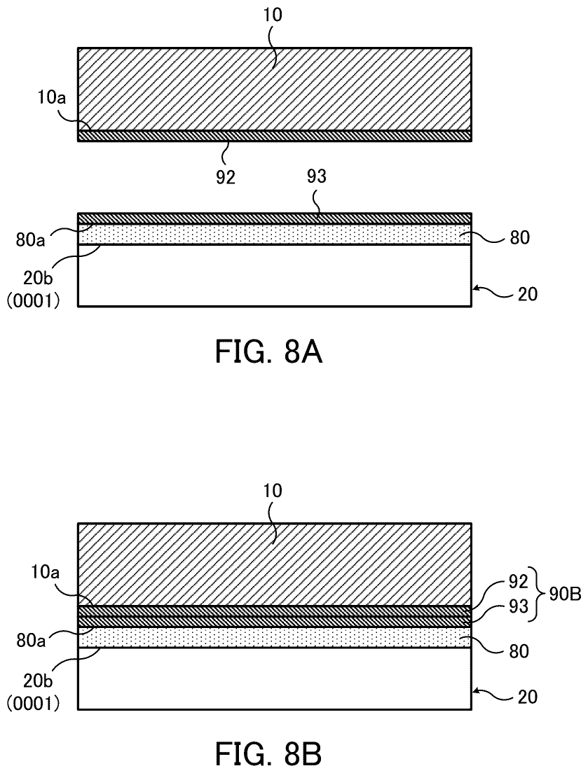

Furthermore, the inorganic insulating film 80 and the support substrate 10 may also be bonded by the use of a method illustrated in FIGS. 8A and 8B. FIG. 8A is a fragmentary schematic sectional view of a process for forming a metal layer on each of the support substrate 10 and the inorganic insulating film 80. FIG. 8B is a fragmentary schematic sectional view of a process for bonding the support substrate 10 and the inorganic insulating film 80.

For example, as illustrated in FIG. 8A, a metal layer 92 is formed on the surface 10a of the support substrate 10 to be bonded to the inorganic insulating film 80. In addition, for example, as illustrated in FIG. 8A, a metal layer 93 is formed on the surface 80a of the inorganic insulating film 80 to be bonded to the support substrate 10. For example, each of the metal layer 92 and the metal layer 93 contains at least one of Si, Ge, Sn, Ti, Al, In, Ni, Au, Pt, Ta, Nb, V, Cr, Zr, Mo, Hf, and W. For example, each of the metal layer 92 and the metal layer 93 is formed by the sputtering method in a vacuum.

After the metal layer 92 and the metal layer 93 are formed, as illustrated in FIG. 8B, the metal layer 92 and the metal layer 93 are brought into contact with each other in a vacuum. As a result, the metal layer 92 and the metal layer 93 are bonded to each other by atomic diffusion therebetween. The support substrate 10 and the inorganic insulating film 80 are bonded to each other via the metal layer 92 and metal layer 93 bonded to each other. The metal layer 92 and the metal layer 93 bonded to each other by atomic diffusion form a metal layer 90B between the support substrate 10 and the inorganic insulating film 80.

After the metal layer 92 and the metal layer 93 are formed and before the metal layer 92 and the metal layer 93 are brought into contact with each other, surface activation may be performed on both or one of the metal layer 92 and the metal layer 93 by irradiation with an ion beam such as Ar.

In addition, an example in which the metal layer 92 and the metal layer 93 are formed on the support substrate 10 and the inorganic insulating film 80 respectively has been described. However, one of the metal layer 92 and the metal layer 93 may be formed.

For example, the metal layer 92 formed on the support substrate 10 and the inorganic insulating film 80 are brought into contact with each other in a vacuum and are bonded to each other by atomic diffusion therebetween. Before the metal layer 92 formed on the support substrate 10 and the inorganic insulating film 80 are brought into contact with each other in a vacuum, surface activation may be performed on both or one of the metal layer 92 and the inorganic insulating film 80 by irradiation with an ion beam of Ar or the like.

Alternatively, the support substrate 10 and the metal layer 93 formed on the inorganic insulating film 80 are brought into contact with each other in a vacuum and are bonded to each other by atomic diffusion therebetween. Before the support substrate 10 and the metal layer 93 formed on the inorganic insulating film 80 are brought into contact with each other in a vacuum, surface activation may be performed on both or one of the support substrate 10 and the metal layer 93 by irradiation with an ion beam of Ar or the like. If surface activation is performed on the support substrate 10, an amorphous layer containing a constituent element of the support substrate 10 may be formed at an interface between the support substrate 10 and the metal layer 93 by amorphization which accompanies bonding after the surface activation.

As described above, the support substrate 10 and the inorganic insulating film 80 may be bonded to each other by the use of the method illustrated in FIGS. 7A and 7B or the method illustrated in FIGS. 8A and 8B. However, the support substrate 10 and the inorganic insulating film 80 may also be bonded by the use of a method other than these methods. Depending on a method used for bonding, the support substrate 10 and the inorganic insulating film 80 may be bonded to each other with a layer different from the amorphous layer 90A and the metal layer 90B interposed therebetween, or the support substrate 10 and the inorganic insulating film 80 may be bonded to each other in a state in which they are in direct contact with each other. Depending on the kind of the support substrate 10 or the kind of the inorganic insulating film 80, a method used for bonding them is properly selected. For convenience, the structure illustrated in FIG. 6B is taken as an example and the following processes are described.

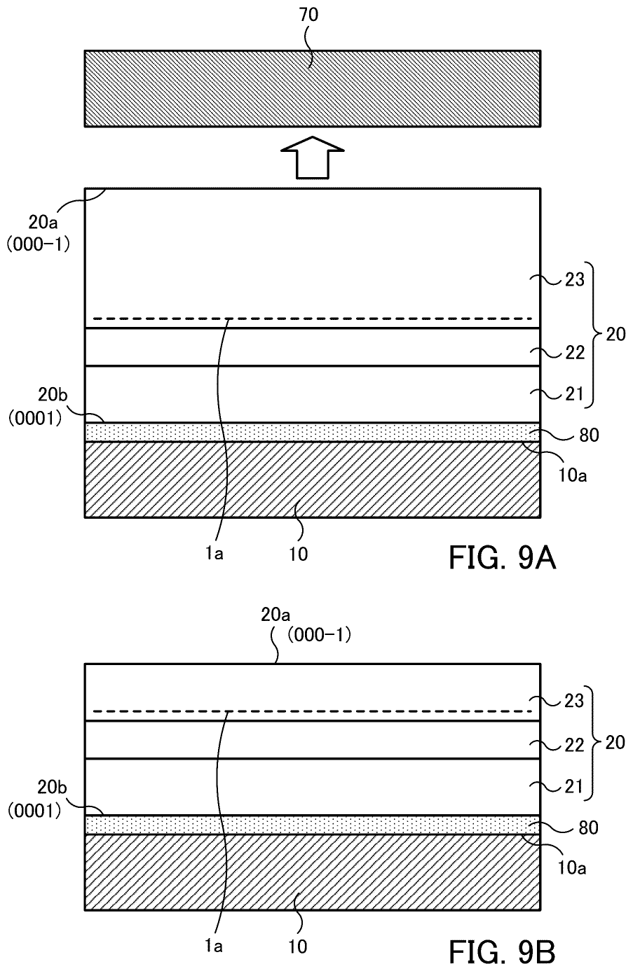

FIG. 9A is a fragmentary schematic sectional view of a process for removing the growth substrate 70. After the support substrate 10 and the inorganic insulating film 80 are bonded to each other, as illustrated in FIG. 9A, the growth substrate 70 is removed from the surface 20a ((000-1) plane) of the nitride semiconductor layer 20. For example, the growth substrate 70 is peeled off and removed from the surface 20a of the nitride semiconductor layer 20 by the use of a laser lift-off method. In addition, the growth substrate 70 may be removed from the surface 20a of the nitride semiconductor layer 20 by the use of a method such as grinding, polishing, wet etching, dry etching, or laser slicing. By removing the growth substrate 70, the channel layer 23 of the nitride semiconductor layer 20, that is, the surface 20a, which is an N-polar plane, is exposed. By removing the growth substrate 70, a structure in which the support substrate 10 is formed on a side opposite to the nitride semiconductor layer 20 of the inorganic insulating film 80 and in which the support substrate 10 supports the nitride semiconductor layer 20 with the inorganic insulating film 80 therebetween is obtained.

FIG. 9B is a fragmentary schematic sectional view of a process for thinning the nitride semiconductor layer 20. After the growth substrate 70 is removed from the nitride semiconductor layer 20, as illustrated in FIG. 9B, the channel layer 23 of the nitride semiconductor layer 20 is thinned. For example, the channel layer 23 is thinned by dry etching using chlorine (Cl)-based gas. The channel layer 23 is thinned to a thickness of 200 nm or less, preferably 50 nm. The surface of the channel layer 23 after the thinning becomes the surface 20a ((000-1) plane), which is an N-polar plane, of nitride semiconductor layer 20. The support substrate 10 supports nitride semiconductor layer 20 with the thinned inorganic insulating film 80 therebetween.

After the channel layer 23 of the nitride semiconductor layer 20 is thinned, an element isolation region (not illustrated) is formed. For example, first a mask (not illustrated) having an opening portion in a region where an element isolation region is to be formed is formed by the use of a photolithography technique. Furthermore, dry etching using Cl-based or gas implantation of ions, such as Ar, is performed on the nitride semiconductor layer 20 in the opening portion of the mask to form an element isolation region. After the element isolation region is formed, the mask is removed.

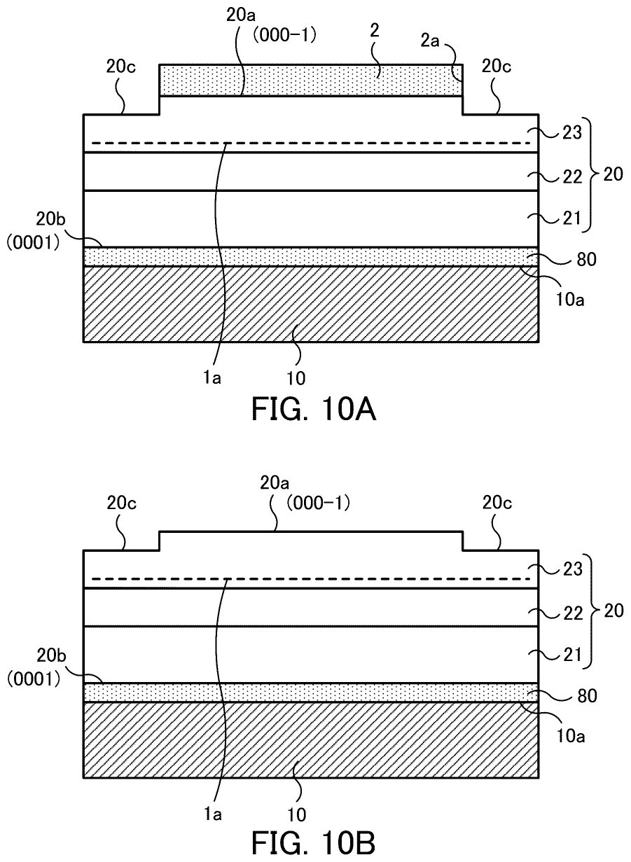

FIG. 10A is a fragmentary schematic sectional view of a process for forming recesses in the nitride semiconductor layer 20. After the channel layer 23 of the nitride semiconductor layer 20 is thinned and the element isolation region is formed, as illustrated in FIG. 10A, recesses 20c are formed in the channel layer 23. The recesses 20c are formed in regions where the source electrode 50 and the drain electrode 60 are to be formed.

When the recesses 20c are formed, as illustrated in FIG. 10A, a surface protective film 2 having opening portions 2a in regions where the recesses 20c are to be formed is formed on the channel layer 23 after the thinning, that is, on the surface 20a of the nitride semiconductor layer 20 after the thinning. For example, various insulating materials, such as an oxide, a nitride, and an oxynitride containing at least one of Si, Al, Hf, Zr, Ti, Ta, and W, are used for forming the surface protective film 2. For example, SiO is used for forming the surface protective film 2. For example, the plasma CVD method is used for forming the surface protective film 2. In addition, the ALD method, the sputtering method, or the like may be used for forming the surface protective film 2. The surface protective film 2 having the opening portions 2a is obtained by, for example, forming a material for the surface protective film 2 on the entire surface by the use of the plasma CVD method or the like and then forming the opening portions 2a in predetermined regions by the use of the photolithography technique and an etching technique.

After the surface protective film 2 having the opening portions 2a is formed, dry etching using Cl-based gas is performed on the channel layer 23 in the opening portions 2a. As a result, as illustrated in FIG. 10A, a part of the channel layer 23 in the opening portions 2a of the surface protective film 2 is removed and the recesses 20c are formed in the channel layer 23.

FIG. 10B is a fragmentary schematic sectional view of a process for removing the surface protective film 2. After the recesses 20c are formed in the channel layer 23, the surface protective film 2 is removed. For example, the surface protective film 2 is removed by the wet etching. As a result, a state illustrated in FIG. 10B is obtained.

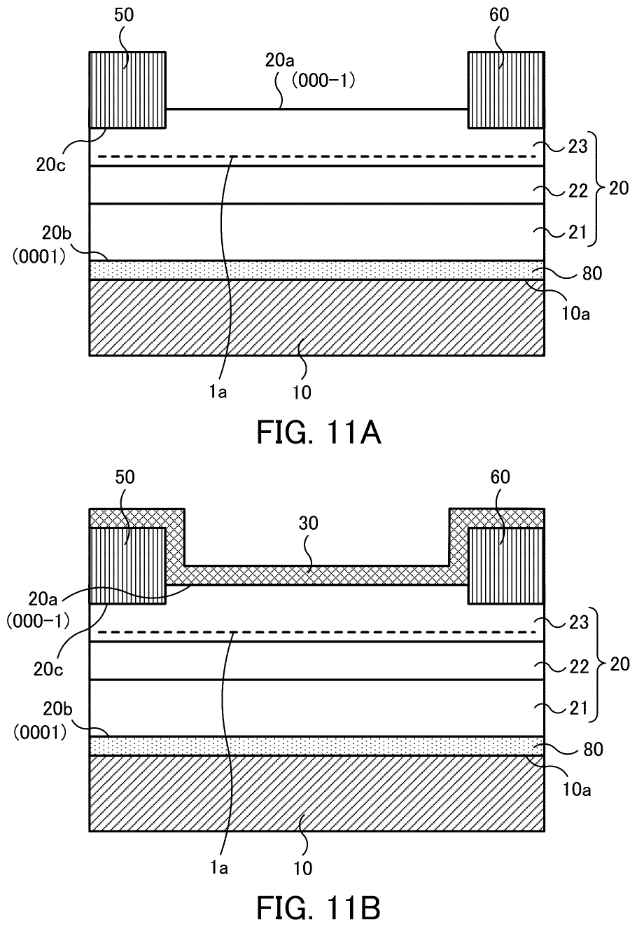

FIG. 11A is a fragmentary schematic sectional view of a process for forming the source electrode 50 and the drain electrode 60. After the surface protective film 2 is removed, as illustrated in FIG. 11A, the source electrode 50 and the drain electrode 60 are formed in the recesses 20c formed in the channel layer 23. At this time, an electrode metal is formed in the recesses 20c using the photolithography technique, a vapor deposition technique, and a lift-off technique. For example, a laminate of Ta having a thickness of 20 nm and Al having a thickness of 200 nm is formed as the electrode metal. After the electrode metal is formed, for example, heat treatment is performed in a nitrogen atmosphere under a temperature condition in the range of 400 to 1000° C., for example, at a temperature of 550° C. By doing so, an ohmic contact of the electrode metal is established. As a result, the source electrode 50 and the drain electrode 60 are formed in the recesses 20c of the channel layer 23.

FIG. 11B is a fragmentary schematic sectional view of a process for forming the passivation film 30. After the source electrode 50 and the drain electrode 60 are formed, as illustrated in FIG. 11B, the passivation film 30 is formed so as to cover the surface 20a of the nitride semiconductor layer 20 (channel layer 23 thereof). The passivation film 30 may be formed so as to cover the source electrode 50 and the drain electrode 60 in addition to the surface 20a of the nitride semiconductor layer 20. For example, various insulating materials, such as an oxide, a nitride, and an oxynitride containing at least one of Si, Al, Hf, Zr, Ti, Ta, and W, are used for forming the passivation film 30. For example, SiN is used for forming the passivation film 30. For example, the passivation film 30 having a thickness in the range of 2 to 500 nm, for example, a thickness of 100 nm is formed by the use of the plasma CVD method. The ALD method, the sputtering method, or the like may be used in place of the plasma CVD method for forming the passivation film 30.

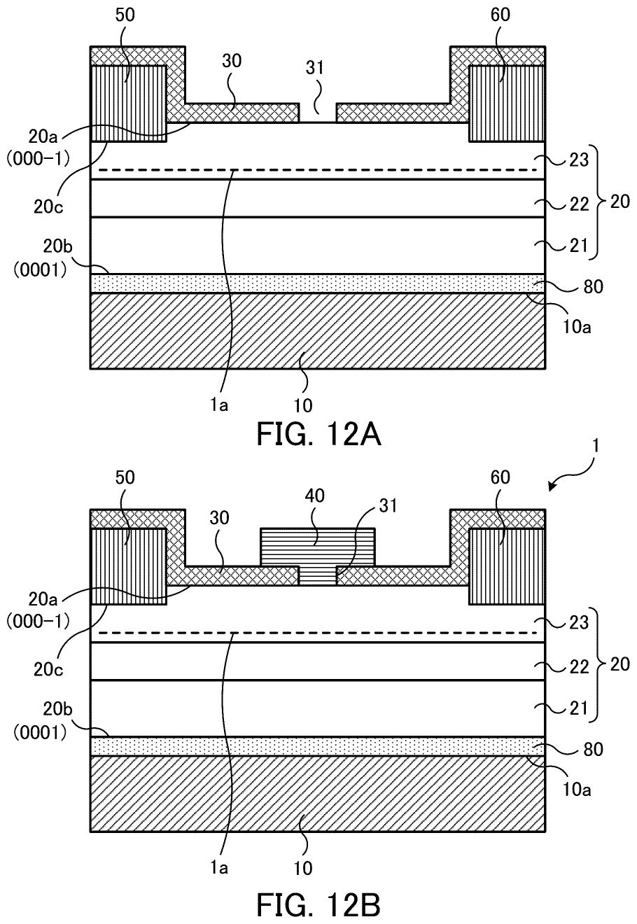

FIG. 12A is a fragmentary schematic sectional view of a process for forming the opening portion 31. After the passivation film 30 is formed, as illustrated in FIG. 12A, the passivation film 30 in a region where the gate electrode 40 is to be formed is partially removed, and the opening portion 31 that leads to the surface 20a of the nitride semiconductor layer 20 is formed. At this time, a mask (not illustrated) having an opening portion in a region where the gate electrode 40 is to be formed is formed by the photolithography technique and dry etching is performed. By this etching, the passivation film 30 exposed from the opening portion of the mask is removed and the opening portion 31 of the passivation film 30 is formed. The passivation film 30 is etched by, for example, dry etching using fluorine (F)-based or Cl-based gas. In addition, the passivation film 30 may be etched by wet etching using hydrofluoric acid, buffered hydrofluoric acid, or the like. After the opening portion 31 is formed by etching the passivation film 30, the mask is removed.

FIG. 12B is a fragmentary schematic sectional view of a process for forming the gate electrode 40. After the opening portion 31 is formed in the passivation film 30, as illustrated in FIG. 12B, the gate electrode 40 is formed in a region including the opening portion 31. At this time, an electrode metal is formed in the region including the opening portion 31 of the passivation film 30 by the use of the photolithography technique, the vapor deposition technique, and the lift-off technique. For example, a laminate of Ni having a thickness of 30 nm and Au having a thickness of 400 nm is formed as the electrode metal. The electrode metal is formed so as to enter the opening portion 31 in addition to the upper surface of the passivation film 30. As a result, the gate electrode 40 which functions as a Schottky electrode is formed.

The semiconductor device 1 illustrated in FIG. 3 (and FIG. 12B) is manufactured by the above processes. That is, an N-polarity HEMT in which the gate electrode 40, the source electrode 50, the drain electrode 60, and the like are formed on the surface 20a ((000-1) plane), which is an N-polar plane, of the nitride semiconductor layer 20 is manufactured.

If the method illustrated in FIGS. 7A and 7B is used for bonding the support substrate 10 and the inorganic insulating film 80, the semiconductor device 1A illustrated in FIG. 4A is manufactured by performing the later processes indicated in the examples of FIGS. 9A to 12B. That is, the semiconductor device 1A having the amorphous layer 90A between the support substrate 10 and the inorganic insulating film 80 is manufactured.

In addition, if the method illustrated in FIGS. 8A and 8B is used for bonding the support substrate 10 and the inorganic insulating film 80, the semiconductor device 1B illustrated in FIG. 4B is manufactured by performing the later processes indicated in the examples of FIGS. 9A to 12B. That is, the semiconductor device 1B having the metal layer 90B between the support substrate 10 and the inorganic insulating film 80 is manufactured.

With the semiconductor device 1 or the like, the kinds and layer structures of the electrode metals used for the gate electrode 40, the source electrode 50, and the drain electrode 60 are not limited to the above examples and the methods for forming them are not limited to the above examples. Each of the gate electrode 40, the source electrode 50, and the drain electrode 60 may have a single-layer structure or a laminated structure. When the source electrode 50 and the drain electrode 60 are formed, the above heat treatment is not always needed as long as an ohmic contact is realized by forming electrode metals for the source electrode 50 and the drain electrode 60. When the gate electrode 40 is formed, heat treatment may be further performed after forming an electrode metal for the gate electrode 40.

An example in which the gate electrode 40 functioning as a Schottky electrode is formed in the semiconductor device 1 or the like is given. However, a MIS type gate structure in which a gate insulating film of an oxide, a nitride, an oxynitride, or the like is formed between the gate electrode 40 and the nitride semiconductor layer 20 may be adopted. Furthermore, in order to increase breakdown voltage, an asymmetric arrangement in which the gate electrode 40 is closer to the source electrode 50 than to the drain electrode 60 may be adopted.

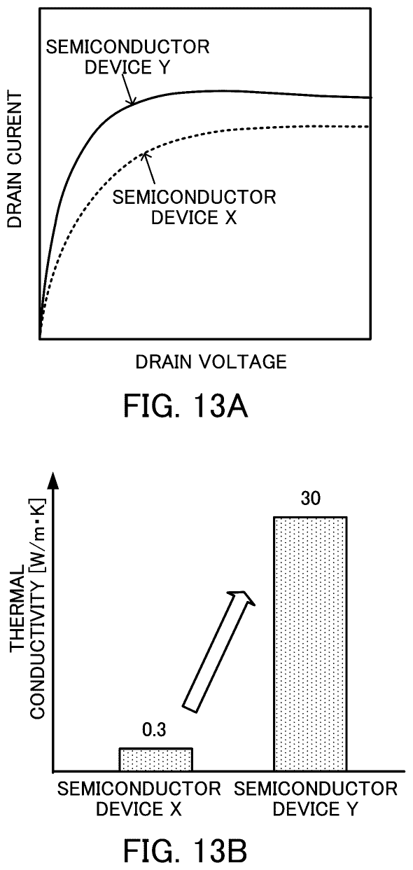

FIGS. 13A and 13B are views for describing examples of the characteristics of the semiconductor device according to the first embodiment. The characteristics of the semiconductor device 100 (also referred to as the “semiconductor device X”) of FIG. 1 manufactured by the use of the method illustrated in FIG. 2B and the characteristics of the semiconductor device 1 (also referred to as the “semiconductor device Y”) of FIG. 3 manufactured by the use of the method illustrated in FIGS. 5A to 12B are compared.

The semiconductor device X (semiconductor device 100 of FIG. 1) is manufactured in the following way by the use of the method illustrated in FIG. 2B. First, the support substrate 110 is bonded to the surface 120b, which is a group-III polar plane, of the nitride semiconductor layer 120 crystal-grown in a group-III polarity direction on the growth substrate 170 with the resin-based adhesive layer 180 using HSQ therebetween. After that, the growth substrate 170 is removed from the surface 120a, which is an N-polar plane, of the nitride semiconductor layer 120. The gate electrode 140, the source electrode 150, the drain electrode 160, and the like are formed on the surface 120a of the nitride semiconductor layer 120 after the growth substrate 170 is removed. The semiconductor device X is manufactured in this way. When the semiconductor device X is manufactured, crystal growth in the group-III polarity direction is used. Therefore, incorporation of impurities, such as O, into the nitride semiconductor layer 120 is suppressed.

Furthermore, the semiconductor device Y (semiconductor device 1 of FIG. 3) is manufactured in the following way by the use of the method illustrated in FIGS. 5A to 12B. First, the non-resin-based inorganic insulating film 80 using SiN as a protective film is formed on the surface 20b, which is a group-III polar plane, of the nitride semiconductor layer 20 crystal-grown in a group-III polarity direction on the growth substrate 70. In addition, the support substrate 10 is bonded to the formed inorganic insulating film 80. After that, the growth substrate 70 is removed from the surface 20a, which is an N-polar plane, of the nitride semiconductor layer 20. The gate electrode 40, the source electrode 50, the drain electrode 60, and the like are formed on the surface 20a of the nitride semiconductor layer 20 after the growth substrate 70 is removed. The semiconductor device Y is manufactured in this way. When the semiconductor device Y is manufactured, crystal growth in the group-III polarity direction is used. Accordingly, incorporation of as impurities, such O, into the nitride semiconductor layer 20 is suppressed.

FIG. 13A illustrates an example of the relationship between a drain voltage and a drain current of the semiconductor device X (semiconductor device 100 of FIG. 1) and an example of the relationship between a drain voltage and a drain current of the semiconductor device Y (semiconductor device 1 of FIG. 3). FIG. 13B illustrates an example of thermal conductivity between the nitride semiconductor layer 120 and the support substrate 110 of the semiconductor device X (semiconductor device 100 of FIG. 1) and an example of thermal conductivity between the nitride semiconductor layer 20 and the support substrate 10 of the semiconductor device Y (semiconductor device 1 of FIG. 3).

As illustrated in FIG. 13A, with the semiconductor device Y (semiconductor device 1 of FIG. 3), a drain current, which is an output, increases compared with the semiconductor device X (semiconductor device 100 of FIG. 1). As described above, with the semiconductor device X, the support substrate 110 is bonded to the nitride semiconductor layer 120 by the resin-based adhesive layer 180 using HSQ. As a result, the defects 102 (FIG. 2B) may occur at the interface between the nitride semiconductor layer 120 and the adhesive layer 180. The defects 102 may cause a current collapse or the like at the time of the operation of the semiconductor device X. On the other hand, with the semiconductor device Y, the nitride semiconductor layer 20 is protected by the non-resin-based inorganic insulating film 80 formed using SiN and the support substrate 10 is bonded to the inorganic insulating film 80. Since the nitride semiconductor layer 20 is protected by the inorganic insulating film 80, the occurrence of defects at the interface between the nitride semiconductor layer 20 and the inorganic insulating film 80 is suppressed. This suppresses the occurrence of a current collapse or the like at the time of the operation of the semiconductor device Y. Therefore, as illustrated in FIG. 13A, with the semiconductor device Y, the drain current increases and the output characteristic improves, compared with the semiconductor device X.

Furthermore, as illustrated in FIG. 13B, thermal conductivity between the nitride semiconductor layer 20 and the support substrate 10 in the semiconductor device Y (semiconductor device 1 of FIG. 3) is significantly higher than thermal conductivity between the nitride semiconductor layer 120 and the support substrate 110 in the semiconductor device X (semiconductor device 100 of FIG. 1). With the semiconductor device X, the resin-based adhesive layer 180 is formed using HSQ having relatively low thermal conductivity between the nitride semiconductor layer 120 and the support substrate 110. On the other hand, with the semiconductor device Y, the non-resin-based inorganic insulating film 80 is formed using SiN having relatively high thermal conductivity between the nitride semiconductor layer 20 and the support substrate 10. Therefore, as illustrated in FIG. 13B, with the semiconductor device Y, the thermal conductivity between the nitride semiconductor layer 20 and the support substrate 10 is higher than the thermal conductivity between the nitride semiconductor layer 120 and the support substrate 110 in the semiconductor device X. As illustrated in FIG. 13B, if SiN is used for forming the inorganic insulating film 80 and HSQ is used for forming the adhesive layer 180, the thermal conductivity (30 W/m·K) between the nitride semiconductor layer 20 and the support substrate 10 of the semiconductor device Y is improved to 100 times the thermal conductivity (0.3 W/m·K) between the nitride semiconductor layer 120 and the support substrate 110 of the semiconductor device X.

As has been described, the semiconductor device 1 or the like includes the high-quality nitride semiconductor layer 20 in which incorporation of impurities, such as O, is suppressed by crystal growth in the group-III polarity direction and in which the occurrence of defects is suppressed by protection with the inorganic insulating film 80. With the semiconductor device 1 or the like, the use of the high-quality nitride semiconductor layer 20 suppresses a decrease in carrier mobility, an increase in leakage current, the occurrence of a current collapse, and the like caused by impurities. As a result, the high output semiconductor device 1 or the like is realized. In addition, since a non-resin-based inorganic insulating material having relatively high thermal conductivity is used for forming the inorganic insulating film 80 between the nitride semiconductor layer 20 and the support substrate 10, deterioration in the property of conducting heat from the nitride semiconductor layer 20 to the support substrate 10 via the inorganic insulating film 80 is suppressed. Furthermore, if a substrate having relatively high thermal conductivity is used as the support substrate 10, the property of dissipating to the outside heat conducted to the support substrate 10 is enhanced. Therefore, deterioration in the operation performance of the semiconductor device 1 or the like caused by overheat of the nitride semiconductor layer 20 is suppressed. According to the above method, the high-quality and high-performance semiconductor device 1 or the like, that is, an N-polarity HEMT is realized.

The resin-based adhesive layer 180 containing an organic component is distinguished from the non-resin-based inorganic insulating film 80 by analysis. In addition, the resin-based adhesive layer 180 formed using HSQ has characteristics different from those of the non-resin-based inorganic insulating film 80. For example, the resin-based adhesive layer 180 formed using HSQ has a high porosity, contains a high concentration of H, and has a low dielectric constant, compared with the non-resin-based inorganic insulating film 80. Therefore, the resin-based adhesive layer 180 formed using HSQ is also distinguished from the non-resin-based inorganic insulating film 80 by analysis.

Furthermore, in the above description the semiconductor device 1 or the like, which is an N-polarity HEMT, are taken as examples. However, other semiconductor device, such as a Schottky barrier diode (SBD), may be realized by the use of the above nitride semiconductor layer 20. For example, an SBD is realized by forming a cathode electrode which functions as an ohmic electrode and an anode electrode which functions as a Schottky electrode on the (000-1) plane side, which is the N-polar plane side, of the nitride semiconductor layer 20, that is, on the surface 20a side of the nitride semiconductor layer 20.

The semiconductor device 1 or the like described above may be applied to various electronic devices. For example, a case where the semiconductor device 1 or the like having the above structure is applied to a semiconductor package, a power factor correction circuit, a power supply device, and an amplifier will be described below.

### Second Embodiment

An example in which the semiconductor device 1 or the like having the above structure is applied to a semiconductor package will now be described as a second embodiment.

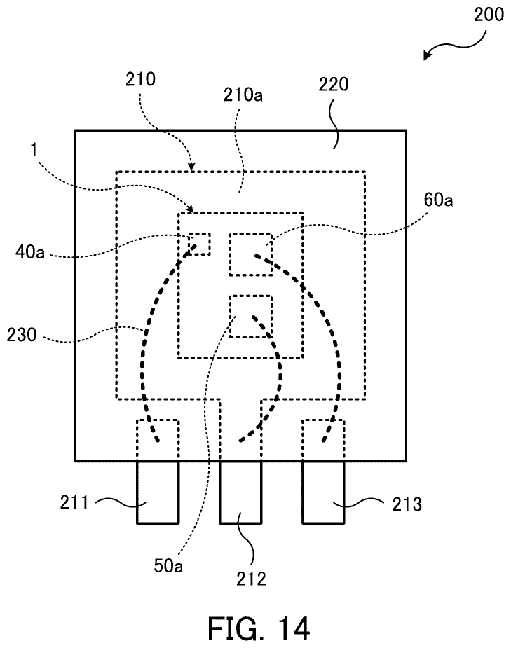

FIG. 14 is a view for describing an example of a semiconductor package according to a second embodiment. FIG. 14 is a fragmentary schematic plan view of an example of a semiconductor package.

A semiconductor package 200 illustrated in FIG. 14 is an example of a discrete package. The semiconductor package 200 includes, for example, the semiconductor device 1 (FIG. 3) described in the above first embodiment, a lead frame 210 on which the semiconductor device 1 is mounted, and resin 220 which seals them.

For example, the semiconductor device 1 is mounted on a die pad 210a of the lead frame 210 by the use of a die attach material or the like (not illustrated). A pad 40a connected to the above gate electrode 40, a pad 50a connected to the source electrode 50, and a pad 60a connected to the drain electrode 60 are formed on the semiconductor device 1. The pad 40a, the pad 50a, and the pad 60a are connected to a gate lead 211, a source lead 212, and a drain lead 213, respectively, of the lead frame 210 by the use of wires 230 made of Au, Al, or the like. The lead frame 210, the semiconductor device 1 mounted on the lead frame 210, and wire 230 which connect the lead frame 210 and the semiconductor device 1 are sealed with the resin 220 so that a part of each of the gate lead 211, the source lead 212, and the drain lead 213 is exposed.

An external connection electrode connected to the source electrode 50 may be formed on a surface of the semiconductor device 1 opposite to a surface on which the pad 40a connected to the gate electrode 40 and the pad 60a connected to the drain electrode 60 are formed. The external connection electrode may be connected to the die pad 210a connected to the source lead 212 by the use of a conductive bonding material such as solder.

For example, the semiconductor device 1 described in the above first embodiment is used and the semiconductor package 200 having the above structure is obtained. The semiconductor device 1 is taken as an example. However, a semiconductor package is obtained in the same way by the use of the semiconductor device 1A or 1B.

As described above, with the semiconductor device 1 or the like, the inorganic insulating film 80 is formed between the support substrate 10 and a (0001) plane, which is a group-III polar of the nitride semiconductor layer 20 crystal-grown in a group-III polarity direction. The gate electrode 40, the source electrode 50, the drain electrode 60, and the like are formed on the (000-1) plane side, which is the N-polar plane side, of the nitride semiconductor layer 20. With the semiconductor device 1 or the like, the high-quality nitride semiconductor layer 20 in which incorporation of impurities and the occurrence of defects are suppressed is realized and a decrease in carrier mobility, an increase in leakage current, the occurrence of a current collapse, and the like are suppressed. Therefore, the high-quality and high-performance semiconductor device 1 or the like, that is, an N-polarity HEMT is realized. By using the semiconductor device 1 or the like, the high-performance semiconductor package 200 is realized.

### Third Embodiment

An example in which the semiconductor device 1 or the like having the above structure is applied to a power factor correction circuit will now be described as a third embodiment.

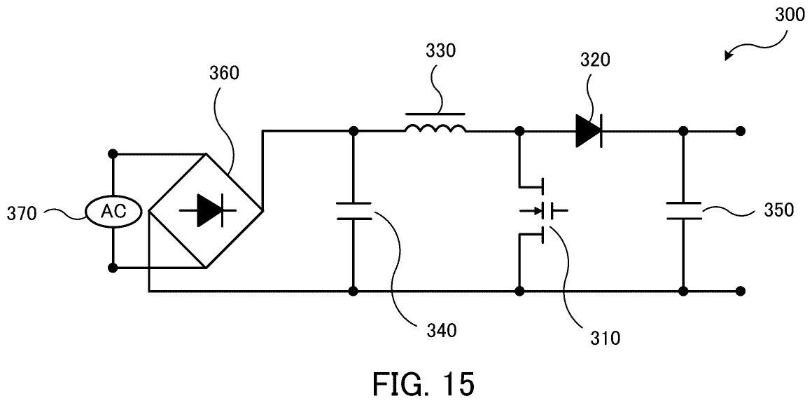

FIG. 15 is a view for describing an example of a power factor correction circuit according to a third embodiment. FIG. 15 is an equivalent circuit diagram of an example of a power factor correction circuit.

A power factor correction (PFC) circuit 300 illustrated in FIG. 15 includes a switching element 310, a diode 320, a choke coil 330, a capacitor 340, a capacitor 350, a diode bridge 360, and an alternating current (AC) power supply 370.

In the PFC circuit 300, a drain electrode of the switching element 310 is connected to an anode terminal of the diode 320 and one terminal of the choke coil 330. A source electrode of the switching element 310 is connected to one terminal of the capacitor 340 and one terminal of the capacitor 350. The other terminal of the capacitor 340 is connected to the other terminal of the choke coil 330. The other terminal of the capacitor 350 is connected to a cathode terminal of the diode 320. Furthermore, a gate driver is connected to a gate electrode of the switching element 310. The AC power supply 370 is connected between both terminals of the capacitor 340 via the diode bridge 360, and a direct current (DC) voltage is taken out of between both terminals of the capacitor 350.

For example, the semiconductor device 1 or the like is used as the switching element 310 of the PFC circuit 300 having the above structure.

As described above, with the semiconductor device 1 or the like, the inorganic insulating film 80 is formed between the support substrate 10 and a (0001) plane, which is a group-III polar plane, of the nitride semiconductor layer 20 crystal-grown in a group-III polarity direction. The gate electrode 40, the source electrode 50, the drain electrode 60, and the like are formed on the (000-1) plane side, which is the N-polar plane side, of the nitride semiconductor layer 20. With the semiconductor device 1 or the like, the high-quality nitride semiconductor layer 20 in which incorporation of impurities and the occurrence of defects are suppressed is realized and a decrease in carrier mobility, an increase in leakage current, the occurrence of a current collapse, and the like are suppressed. Therefore, the high-quality and high-performance semiconductor device 1 or the like, that is, an N-polarity HEMT is realized. The high-performance PFC circuit 300 is realized by the use of the semiconductor device 1 or the like.

### Fourth Embodiment

An example in which the semiconductor device 1 or the like having the above structure is applied to a power supply device will now be described as a fourth embodiment.

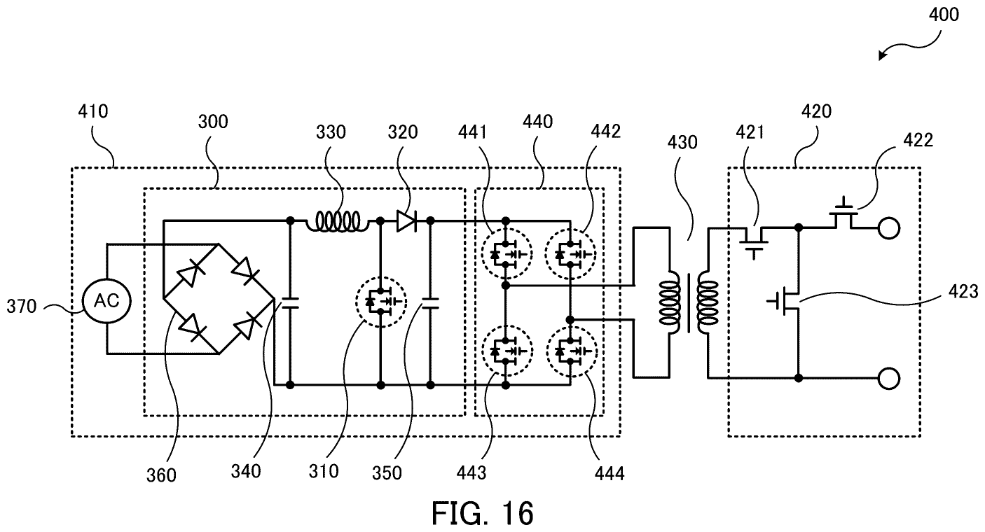

FIG. 16 is a view for describing an example of a power supply device according to a fourth embodiment. FIG. 16 is an equivalent circuit diagram of an example of a power supply device.

A power supply device 400 illustrated in FIG. 16 includes a primary-side circuit 410, a secondary-side circuit 420, and a transformer 430 located between the primary-side circuit 410 and the secondary-side circuit 420.

The primary-side circuit 410 includes the PFC circuit 300 described in the above third embodiment and an inverter circuit connected between both terminals of the capacitor 350 of the PFC circuit 300. The inverter circuit is, for example, a full-bridge inverter circuit 440. The full-bridge inverter circuit 440 includes a plurality of, for example, four switching elements 441, 442, 443, and 444.

The secondary-side circuit 420 includes a plurality of, for example, three switching elements 421, 422, and 423.

For example, the semiconductor device 1 or the like is used as the switching element 310 of the PFC circuit 300 included in the primary-side circuit 410 and the switching elements 441 to 444 of the full-bridge inverter circuit 440 of the power supply device 400 having the above structure. For example, a normal MIS FETs using Si is used as the switching elements 421, 422, and 423 of the secondary-side circuit 420 of the power supply device 400.

As described above, with the semiconductor device 1 or the like, the inorganic insulating film 80 is formed between the support substrate 10 and a (0001) plane, which is polar a group-III plane, of the nitride semiconductor layer 20 crystal-grown in a group-III polarity direction. The gate electrode 40, the source electrode 50, the drain electrode 60, and the like are formed on the (000-1) plane side, which is the N-polar plane side, of the nitride semiconductor layer 20. With the semiconductor device 1 or the like, the high-quality nitride semiconductor layer 20 in which incorporation of impurities and the occurrence of defects are suppressed is realized and a decrease in carrier mobility, an increase in leakage current, the occurrence of a current collapse, and the like are suppressed. Therefore, the high-quality and high-performance semiconductor device 1 or the like, that is, an N-polarity HEMT is realized. By using the semiconductor device 1 or the like, the high-performance power supply device 400 is realized.

### Fifth Embodiment

An example in which the semiconductor device 1 or the like having the above structure is applied to an amplifier will now be described as a fifth embodiment.

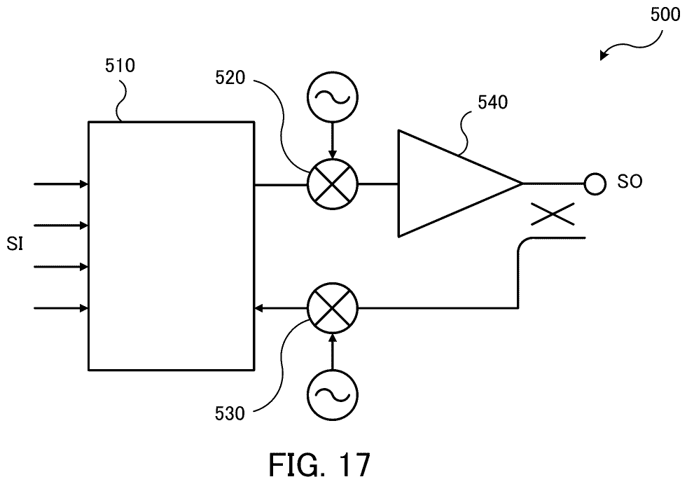

FIG. 17 is a view for describing an example of an amplifier according to a fifth embodiment. FIG. 17 is an equivalent circuit diagram of an example of an amplifier.

An amplifier 500 illustrated in FIG. 17 includes a digital predistortion circuit 510, a mixer 520, a mixer 530, and a power amplifier 540.

The digital predistortion circuit 510 compensates for nonlinear distortion of an input signal. The mixer 520 mixes an input signal SI whose nonlinear distortion has been compensated for with an AC signal. The power amplifier 540 amplifies a signal obtained by mixing the input signal SI with the AC signal. With the amplifier 500, for example, by switching a switch, an output signal SO may be mixed with an AC signal by the mixer 530 and a signal obtained may be sent to the digital predistortion circuit 510. The amplifier 500 may be used as a high-frequency amplifier or a high output amplifier.

The semiconductor device 1 or the like is used as the power amplifier 540 of the amplifier 500 having the above structure.

As described above, with the semiconductor device 1 or the like, the inorganic insulating film 80 is formed between the support substrate 10 and a (0001) plane, which is a group-III polar plane, of the nitride semiconductor layer 20 crystal-grown in a group-III polarity direction. The gate electrode 40, the source electrode 50, the drain electrode 60, and the like are formed on the (000-1) plane side, which is the N-polar plane side, of the nitride semiconductor layer 20. With the semiconductor device 1 or the like, the high-quality nitride semiconductor layer 20 in which incorporation of impurities and the occurrence of defects are suppressed is realized and a decrease in carrier mobility, an increase in leakage current, the occurrence of a current collapse, and the like are suppressed. Therefore, the high-quality and high-performance semiconductor device 1 or the like, that is, an N-polarity HEMT is realized. The high-performance amplifier 500 is realized by using the semiconductor device 1 or the like.

Various electronic devices (semiconductor package 200, the PFC circuit 300, the power supply device 400, the amplifier 500 described in the second to fifth embodiments, and the like) to which the semiconductor device 1 or the like is applied may be mounted on various electronic devices. For example, they may be mounted on various electronic devices such as a computer (a personal computer, a supercomputer, a server, or the like), a smartphone, a mobile phone, a tablet terminal, a sensor, a camera, an audio device, a measurement device, an inspection device, a manufacturing device, a transmitter, a receiver, and a radar device.

According to an aspect, a high-quality and high-performance semiconductor device is realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a nitride semiconductor layer having a (0001) plane and a (000-1) plane opposite to the (0001) plane;
a non-resin-based inorganic insulating film formed on a (0001) plane side of the nitride semiconductor layer where the (0001) plane is located; and
a support substrate which is formed on a side of the inorganic insulating film opposite to the nitride semiconductor layer and which supports the nitride semiconductor layer with the inorganic insulating film therebetween.

2. The semiconductor device according to claim 1, wherein the inorganic insulating film contains an oxide, a nitride, or an oxynitride made of at least one of silicon, titanium, or aluminum.

3. The semiconductor device according to claim 1, further comprising an amorphous layer provided between the inorganic insulating film and the support substrate.

4. The semiconductor device according to claim 1, further comprising a metal layer provided between the inorganic insulating film and the support substrate.

5. The semiconductor device according to claim 1, wherein the support substrate has higher thermal conductivity than the nitride semiconductor layer.

6. The semiconductor device according to claim 1, wherein the nitride semiconductor layer includes:
a channel layer containing a first nitride semiconductor; and
a barrier layer provided between the channel layer and the inorganic insulating film and containing a second nitride semiconductor having a band gap larger than a band gap of the first nitride semiconductor.

7. The semiconductor device according to claim 6, wherein the nitride semiconductor layer includes a buffer layer provided between the barrier layer and the inorganic insulating film and containing a third nitride semiconductor different from the second nitride semiconductor.

8. The semiconductor device according to claim 1, further comprising:
a source electrode and a drain electrode provided separately from each other on a (000-1) plane side of the nitride semiconductor layer where the (000-1) plane is located; and
a gate electrode formed between the source electrode and the drain electrode on the (000-1) plane side of the nitride semiconductor layer.

9. A semiconductor device manufacturing method comprising:
forming a nitride semiconductor layer on a growth substrate so that the nitride semiconductor layer has a (000-1) plane on a (000-1) plane side where the growth substrate is located and has a (0001) plane on a side opposite to the growth substrate;
forming a non-resin-based inorganic insulating film on a (0001) plane side of the nitride semiconductor layer where the (0001) plane is located;
bonding a support substrate which supports the nitride semiconductor layer with the inorganic insulating film therebetween to a side of the inorganic insulating film opposite to the nitride semiconductor layer; and
removing the growth substrate on the (000-1) plane side of the nitride semiconductor layer after bonding the support substrate.

10. The semiconductor device manufacturing method according to claim 9, wherein the inorganic insulating film contains an oxide, a nitride, or an oxynitride made of at least one of silicon, titanium, or aluminum.

11. The semiconductor device manufacturing method according to claim 9, further comprising performing a surface activation by an ion beam irradiation on one or both of surfaces of the inorganic insulating film and the support substrate to be bonded to each other before bonding the support substrate.

12. The semiconductor device manufacturing method according to claim 9, further comprising forming a metal layer on one or both of surfaces of the inorganic insulating film and the support substrate to be bonded to each other before bonding the support substrate.

13. The semiconductor device manufacturing method according to claim 9, wherein the support substrate has higher thermal conductivity than the nitride semiconductor layer.

14. The semiconductor device manufacturing method according to claim 9, wherein the forming the nitride semiconductor layer on the growth substrate includes:
forming a channel layer containing a first nitride semiconductor; and
forming a barrier layer containing a second nitride semiconductor having a band gap larger than a band gap of the first nitride semiconductor, on a side of the channel layer opposite to the growth substrate.

15. The semiconductor device manufacturing method according to claim 14, wherein the forming the nitride semiconductor layer includes forming a buffer layer containing a third nitride semiconductor different from the second nitride semiconductor, on a side of the barrier layer opposite to the channel layer.

16. The semiconductor device manufacturing method according to claim 9, further comprising, after the removing the growth substrate:
forming a source electrode and a drain electrode separately from each other on the (000-1) plane side of the nitride semiconductor layer; and
forming a gate electrode between the source electrode and the drain electrode on the (000-1) plane side of the nitride semiconductor layer.

17. An electronic device comprising:
a semiconductor device including:
a nitride semiconductor layer having a (0001) plane and a (000-1) plane opposite to the (0001) plane;
a non-resin-based inorganic insulating film formed on a (0001) plane side of the nitride semiconductor layer where the (0001) plane is located; and
a support substrate which is formed on a side of the inorganic insulating film opposite to the nitride semiconductor layer and which supports the nitride semiconductor layer with the inorganic insulating film therebetween.
